(19) United States
(12) Patent Application Publication
(10) Pub. No.: US 2014/0332847 A1
(43) Pub. Date: Nov. 13, 2014

(54) Composite One-Piece IGBT Device and Producing Method Thereof

(71) Applicant: TSINGHUA UNIVERSITY, Beijing (CN)

(72) Inventors: Liren Yan, Beijing (CN); Daoguang Liu, Beijing (CN); Zhihong Liu, Beijing (CN); Wei Zhang, Beijing (CN); Wei Zhou, Beijing (CN); Jie Cui, Beijing (CN)

(21) Appl. No.: 14/372,190

(22) PCT Filed: Jul. 17, 2013
(86) PCT No.: PCT/CN2013/079554

§ 371 Date: Jul. 14, 2014

(30) Foreign Application Priority Data
Nov. 13, 2012 (CN) 201210452249.7

(51) Int. Cl. H01L 27/082; H01L 29/40; H01L 29/739

(52) U.S. Cl. CPC H01L 27/0823; H01L 29/7395; H01L 29/404
USPC 257/140; 438/135

(57) ABSTRACT

A composite one-piece IGBT power device is disclosed to solve a problem that existing devices' turning-on/off speed is not high enough. The composite one-piece IGBT device of the present invention comprises at least two IGBT devices. Drift regions of the at least two IGBT devices connect with each other and electrodes of the at least two IGBT devices are led out separately from each other. The composite one-piece IGBT device may also consist of four IGBT devices. The drift regions of the four IGBT devices connect with each other. The composite IGBT device may also be embodied as two IGBT devices connected with each other. One of the two IGBT devices acts as a primary switching device for switching a large current, and the other acts as an auxiliary device for accelerating the switching action of the primary switching device. The composite IGBT device of the present invention is formed through a producing method which adds a few steps such as forming grooves to the conventional IGBT manufacturing process. The present invention is inexpensive and easy to implement, and provides a benefit of further increasing an operating speed by using two or more IGBT devices which promote each other's turning-on/off speed.

### BACKGROUND OF THE INVENTION

1. Technical Field

The present invention relates to a composite one-piece IGBT power device and a producing method thereof.

2. Description of Related Art

Insulated gate bipolar transistors (IGBT) are one of the dominant power electronic devices suitable for medium and high power conversion applications. Especially in a case of a high turning-on/off speed, a size and a weight of the power supply system is largely reduced, while the power consuming efficiency and the conversion quality will be increased enormously. Therefore, in terms of energy conservation and emission reduction and sustainable development of national economy, the IGBTs are a kind of important basic devices for power conversion and control.

An IGBT may be considered as a composite of two structures, i.e., a bipolar transistor and a field effect transistor. The IGBT may also be considered as a combination of a metal oxide semiconductor (MOS) device fabricated on an upper surface of a wafer and a PN junction diode fabricated on a bottom surface of the wafer. The MOS device at the upper surface and the diode at the lower surface are connected with each other via an N− drift region of a semiconductor material. A longer N− drift region of the semiconductor material (i.e., a thicker wafer) allows for a higher withstand voltage of the IGBT device; and otherwise, the withstand voltage is lower.

A conventional producing method of a non-punch through (NPT) IGBT device is divided into two steps, which may be termed as a pre-process and a post-process. The pre-process processes the upper surface of the wafer (also termed as the front surface of the wafer), and the post-process processes the bottom surface (also termed as the back surface of the wafer). In the pre-process, a lot of MOS device structures are fabricated simultaneously on one wafer. After all the process is accomplished, a passivation is performed on the front-surface devices to provide protection. Afterwards, the procedure proceeds to the post-process. The post-process comprises the following steps of: thinning the wafer at the back surface (to a thickness suitable for the withstand voltage requirement); performing ion implantation, annealing for impurity activation, and metallization on the entire back surface; slicing the wafer; electrode pressure welding; and packing the IGBT device, and so on. In this way, a finished IGBT device product is accomplished. However, a primary problem with the current IGBT devices is that the turning-on/off speed of the device operation is still not high enough.

### BRIEF SUMMARY OF THE INVENTION

To overcome the aforesaid shortcoming, the present invention provides a one-piece IGBT device having a higher turning-on/off speed.

To achieve the aforesaid objective, the present invention provides a composite IGBT device. The composite IGBT device comprises at least two IGBT devices. Drift regions of the at least two IGBT devices contact with each other and electrodes of the at least two IGBT devices are led out separately from each other.

Specifically, the composite IGBT device is in a “ [symbol] ” shape consisting of four IGBT devices. The drift region of each of the IGBT devices contacts with those of the adjacent IGBT devices.

Further speaking, the IGBT device at the upper left corner and the IGBT device at the lower right corner are connected in parallel to form a first block. The IGBT device at the upper right corner and the IGBT device at the lower left corner are connected in parallel to form a second block. The two blocks are in operating states of turning-on and turning-off alternately.

Specifically, the composite IGBT device consists of IGBT devices which have the same size or have different sizes. When sub-devices of the composite IGBT device have different sizes, one of the IGBT devices that occupies a larger chip area acts as a primary switching device for switching a large current, while another adjacent IGBT device that occupies a smaller chip area acts as an auxiliary device for accelerating the switching action of the primary switching device.

Specifically, in the composite IGBT device, the sub-IGBT devices constituting the composite structure are separated from each other spatially. In addition to forming deep groove between the sub-devices at the upper surface and the lower surface for isolation, other isolating technologies including forming a field ring, forming a field plate and a certain combination of these isolating technologies are used in each sub-IGBT device.

On the other hand, the present invention provides a producing method of a composite IGBT device, which comprises the following steps of:

8.1 forming a channel region of a second conductivity type on a substrate wafer of a first conductivity type through impurity doping and diffusion; preparing a gate, and forming a source region of the first conductivity type through impurity implantation and doping activation; depositing a protective medium layer, forming a contact via, and performing a metallization wiring process and upper surface passivation;

8.2 before, during or after the step 8.1, forming a groove on the upper surface and depositing a passivation layer to protect the bared portion;

8.3 thinning a back surface of the wafer;

8.4 performing ion implantation doping, annealing and metallization on the back surface;

8.5 before, during or after the step 8.4, forming a back-surface groove on the back surface at a position corresponding to the upper-surface groove; and

8.6 slicing the wafer, and leading out electrodes of individual devices of the composite IGBT device respectively; and packing the composite IGBT device.

Specifically, the upper-surface groove is formed in the step 8.2 through wet etching, dry etching, dry-and-wet etching or laser ablating.

Specifically, the back-surface groove is formed in the step 8.5 through the following steps of:

8.5.1 performing light exposure on the back surface at a position corresponding to the upper-surface groove through a double-side aligned photolithography process; and

8.5.2 forming the back-surface groove through wet etching, dry etching, dry-and-wet etching or laser ablating.

Finally, the composite IGBT device of the present invention is formed by connecting N− drift regions of the IGBT devices with connections. A use of the composite IGBT is characterized in that, two or two sets of IGBT devices operate in such a way that one or one set of IGBT devices are turned on while the other or the other set of IGBT devices are turned off; and vice versa. Therefore, the IGBT devices can promote each other's turning-on/off speed. As a result, a benefit of further increasing the operating speed is achieved.

The composite IGBT device of the present invention is formed through the producing method which adds a few steps such as forming grooves to the current IGBT device producing method. The present invention is inexpensive and easy to implement. On the other hand, if, in a practical application, emitter electrodes of the two sub-IGBT devices at the lower surface are connected to the same potential, then the step of forming grooves may also be eliminated provided that the two sub-devices are sufficiently isolated from each other. This makes the implementation easier.

### BRIEF DESCRIPTION OF THE SEVERAL VIEWS OF THE DRAWINGS

FIG. 1 is a schematic structural view of a first preferred embodiment of the present invention;

FIG. 2 is a schematic structural view of a third preferred embodiment of the present invention;

FIG. 3 is a schematic view of a fifth preferred embodiment of the present invention; and

FIG. 4 is a schematic view of a sixth preferred embodiment of the present invention.

In the drawings, when 1 represents an N+ type conduction region, then 2 represents a P type semiconductor region, 3 represents an N− region, 4 represents an N− connection region, 5 represents a P or P+ region, 6 represents a gate, 7 represents a sub-device constituting a composite IGBT, and 8 represents a deep groove for isolation at the upper surface.

When 1 represents a P+ type conduction region, then 2 represents an N type semiconductor region, 3 represents a P− region, 4 represents a P− connection region, 5 represents an N or N+ region, 6 represents a gate, 7 represents a sub-device constituting a composite IGBT, and 8 represents a deep groove for isolation at the upper surface.

In the drawings, 11 represents an NPT type composite IGBT device of which the underside is a P+ region, 12 represents an NPT type composite IGBT device of which the underside is an N+ region, and 13 represents a transformer.

### DETAILED DESCRIPTION OF THE INVENTION

In the following descriptions, the present invention will be detailed with reference to the attached drawings and preferred embodiments thereof.

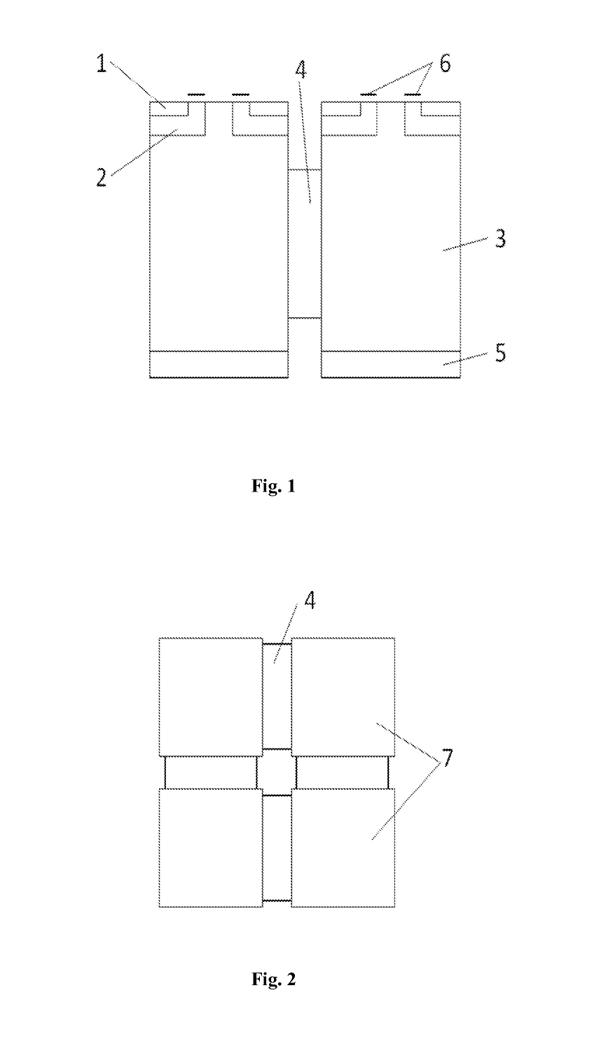

In a first preferred embodiment as shown in FIG. 1, a composite IGBT device consists of two conventional IGBT devices, which are connected with each other via a drift region connection 4. Each of the IGBT devices comprises an MOS structure at a front surface and a PN junction at a bottom surface. The MOS structure at the front surface is constituted by an N+ source-drain region 1, a P type channel region 2 and an N type drift region 3. The PN junction structure at the bottom surface is constituted by a P+ bottom surface region 5 and an N type drift region 3.

The MOS structure is fabricated on the front surface of a wafer through the conventional process. In other words, the P type region 2 is formed on an N− type substrate wafer (which is used as a substrate) through impurity doping and diffusion. Then a gate 6 is prepared, and the N+ type source region 1 is formed through impurity implantation and activation. A protective medium layer is deposited on the upper surface of the resultant structure. Afterwards, a contact via is formed, and then a metallization wiring process and upper surface passivation are performed.

A deep groove is formed on the upper surface at an area between the two IGBT devices through wet etching. Then a passivation layer is deposited to protect the bared portion.

The back surface is processed as with conventional IGBT devices. In other words, the wafer is thinned at the back surface, and ion implantation doping, annealing and metallization are performed on the back surface.

Light exposure is performed on the back surface through a double-side aligned photolithography process. A deep groove is formed on the back-surface at the connection region of the two IGBT devices through wet etching.

The two IGBT devices are sliced from the wafer as a whole. Electrodes of the individual IGBT devices are led out respectively. An emitter of the IGBT device is led out from the source region, and a collector of the IGBT device is led out from the bottom surface region. Finally, the two IGBT devices are packed together to form a one-piece IGBT device product.

In this preferred embodiment, the two IGBT devices are connected with each other via the drift region connection to form the composite or one-piece IGBT device. The one-piece IGBT device operates in an operating state in which the first IGBT device is turned on while the second IGBT device is turned off, and vice versa. When a turning-on/off state in which the first IGBT device is turned on and the second IGBT device is turned off is switched to another turning-on/off state in which the first IGBT device is turned off and the second IGBT device is turned on, carriers accumulated in the N− region of the first IGBT device can be drained to the N− region of the second IGBT device rapidly. Therefore, the turning-off speed of the first IGBT device increases, and so does the turning-on speed of the second IGBT device. As a result, the turning-on/off speed of the whole device is increased. The composite IGBT device having performances of the conventional IGBT device has a significantly increased turning-on/off speed, but is not a simple sum of two IGBT devices. When acting as an inverter power supply, the current IGBT device usually operates at an operating frequency of about 20 kHz. In this preferred embodiment, the operating frequency of the one-piece IGBT device may be up to 30-50 kHz or even more.

In a second preferred embodiment, the composite IGBT device consists of two conventional IGBT devices, which are connected with each other via the drift region connection. Different from the first preferred embodiment, one of the two conventional IGBT devices occupies a larger area and is referred to as a primary switching device, while the other conventional IGBT device occupies a smaller area and is referred to as an accelerating switching device. Each of the IGBT devices comprises an MOS structure at the front surface and a PN junction at the bottom surface. The MOS structure at the front surface is constituted by an N+ source-drain region, a P type channel region and an N type drift region acting as a source-drain region. The PN junction structure at the bottom surface is constituted by a P+/N+ bottom surface region and an N type drift region.

A deep groove is formed on the upper surface area of the wafer through dry etching. Then the MOS structure is fabricated on the front surface of the wafer through the conventional process. In other words, a P type region is formed on an N− type substrate wafer (which is used as a substrate) through impurity doping and diffusion. Then a gate is prepared, and an N+ type source region is formed through impurity implantation and activation. A protective medium layer is deposited on the upper surface of the resultant structure. Afterwards, a contact via is formed, and then a metallization wiring process and upper surface passivation are performed.

The back surface is processed as with conventional IGBT devices. In other words, the wafer is thinned at the back surface, and ion implantation doping, annealing and metallization are performed on the back surface.

Light exposure is performed on the back surface through a double-side aligned photolithography process. A deep groove is formed on the back-surface at a position corresponding to the upper-surface deep groove through dry etching in such a way that the two IGBT devices remain connected with each other only at the connection region. The two IGBT devices are sliced from the wafer as a whole. Electrodes of the individual IGBT devices are led out respectively. Finally, the two IGBT devices consisting of the bigger IGBT device and the smaller IGBT device are packed together to form a one-piece IGBT device product.

In this preferred embodiment, the bigger IGBT device and the smaller IGBT device are connected with each other via the drift region connection to form the composite IGBT device. The composite IGBT device operates in an operating state in which one IGBT device is turned on while the other is turned off, and vice versa. At the moment when the turning-on/off state of the primary device is switched, carriers accumulated in the drift region may flow to the area of the accelerating IGBT device from the area of the primary IGBT device, or flow to the primary switching device from the area of the accelerating IGBT device to supplement carriers. As a result, the turning on/off time of the primary device is shortened, the turning-on/off speed of the device is increased, and the working performance of the IGBT device is improved as a whole. The composite IGBT device having performances of the conventional IGBT device has a significantly increased turning-on/off speed, but is not a simple sum of two IGBT devices.

In a third preferred embodiment as shown in FIG. 2, the composite IGBT device is in a “ [symbol] ” shape consisting of four conventional IGBT devices 7. The four IGBT devices 7 are connected with each other via drift region connections 4. Each of the IGBT devices comprises an MOS structure at the front surface and a PN junction at the bottom surface. The MOS structure at the front surface is constituted by an N+ source-drain region, a P type channel region and an N type drift region acting as a source-drain region. The PN junction structure at the bottom surface is constituted by a P+/N+ bottom surface region and an N type drift region.

A deep groove is formed on the upper surface area of the wafer through dry etching. Then the MOS structure is fabricated on the front surface of the wafer through the conventional process. In other words, a P type region is formed on an N− type substrate wafer (which is used as a substrate) through impurity doping and diffusion. Then a gate is prepared, and an N+ type source region is formed through impurity implantation and activation. A protective medium layer is deposited on the upper surface of the resultant structure. Afterwards, a contact via is formed, and then a metallization wiring process and upper surface passivation are performed.

The wafer is thinned at the back surface. Light exposure is performed on the back surface through a double-side aligned photolithography process. A deep groove is formed on the back-surface at a position corresponding to the upper-surface deep groove through dry etching in such a way that every two adjacent IGBT devices remain connected with each other only at the connection region. The back surface is processed as with the conventional IGBT devices. In other words, ion implantation doping, annealing and metallization are performed on the back surface.

The four IGBT devices are sliced from the wafer as a whole. Electrodes of the individual IGBT devices are led out respectively. Finally, the four IGBT devices are packed together to form a composite IGBT device product.

In this preferred embodiment, the four IGBT devices are connected with each other via drift region connections to form the one-piece IGBT device in the “ [symbol] ” shape. The one-piece IGBT device operates in a state in which a certain IGBT device is turned on while adjacent IGBT devices are turned off, and vice versa. The four IGBTs may be turned on and off alternately. At the moment when the turning-on/off state is switched, carriers accumulated in the drift region may flow from one IGBT device area to another IGBT device area. As a result, the turning-on/off speed of the device and the turning-on/off speeds of the adjacent devices are increased, and the operating performance of the IGBT device is improved as a whole. The composite IGBT device having performances of the conventional IGBT device has a significantly increased turning-on/off speed, but is not a simple sum of two IGBT devices.

In a fourth preferred embodiment, the composite IGBT device is in a “ [symbol] ” shape consisting of four conventional IGBT devices. The four IGBT devices are connected with each other via drift region connections. Each of the IGBT devices comprises an MOS structure at the front surface and a PN junction at the bottom surface. The MOS structure at the front surface is constituted by an N+ source-drain region, a P type channel region and an N type drift region acting as a source-drain region. The PN junction structure at the bottom surface is constituted by a P+/N+ bottom surface region and an N type drift region.

The MOS structure is fabricated on the front surface through the conventional process. In other words, a P type region is formed on an N− type substrate wafer (which is used as a substrate) through impurity doping and diffusion. Then a gate is prepared, and an N+ type source region is formed through impurity implantation and activation. A protective medium layer is deposited on the upper surface of the resultant structure. Afterwards, a contact via is formed, and then a metallization wiring process and upper surface passivation are performed. During this process, a deep groove is formed on the upper surface area of the wafer through dry etching.

The back surface is processed as with the conventional IGBT devices. In other words, the wafer is thinned at the back surface, and ion implantation doping, annealing and metallization are performed on the back surface. During this process, light exposure is performed on the back surface through a double-side aligned photolithography process. A deep groove is formed on the back-surface at a position corresponding to the upper-surface deep groove through dry etching in such a way that every two adjacent IGBT devices remain connected with each other only at the connection region.

The four IGBT devices are sliced from the wafer as a whole. Finally, the four IGBT devices are packed together to form a one-piece IGBT device product. The IGBT device at the upper left corner and the IGBT device at the lower right corner are connected in parallel to form a first block, and the IGBT device at the upper right corner and the IGBT device at the lower left corner are connected in parallel to form a second block. Therefore, a one-piece IGBT device consisting of two blocks integrated to each other is formed.

In this preferred embodiment, the four IGBT devices are connected with each other via drift region connections. In a case where the turned-on IGBT device at the upper left corner is switched to be turned off, carriers accumulated in the IGBT device during it is turned on may be drained to the IGBT device region at the upper right corner and may also be drained to the IGBT device region at the lower left corner. As a result, the draining efficiency is improved, and the operating speed of the device is further increased.

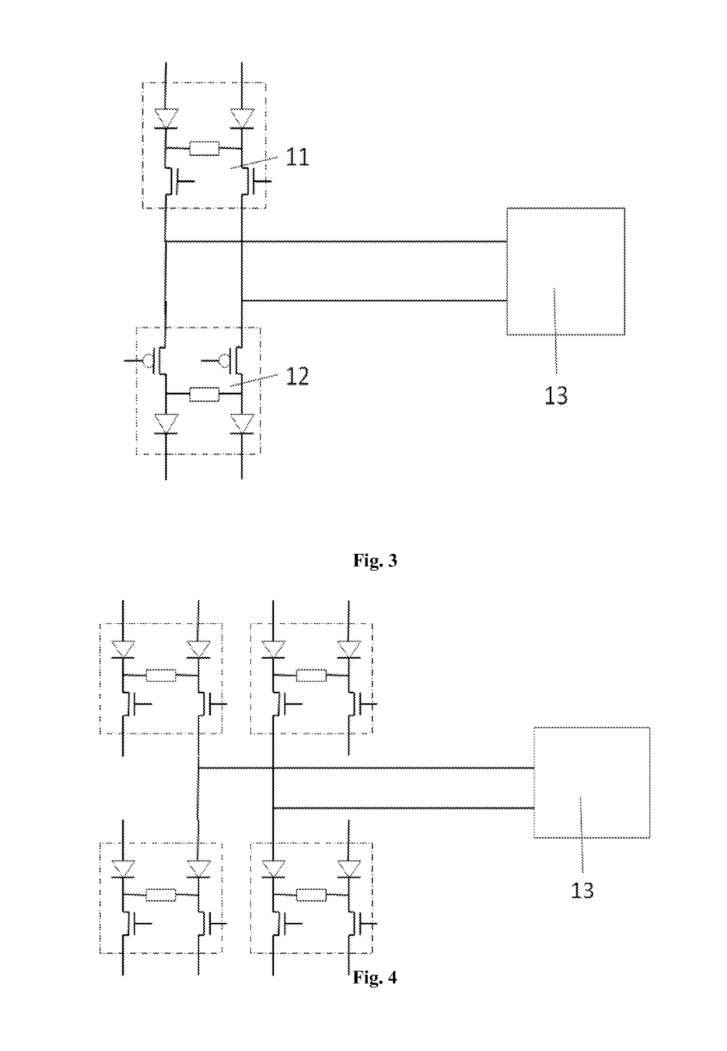

In a fifth preferred embodiment as shown in FIG. 3, two composite IGBTs of complementary conduction types may constitute a full-bridge circuit. The full-bridge circuit is configured to control a current direction in a primary coil of a transformer and is used as a core module circuit for switch control in a high-quality power supply. The structure of the IGBT device may be considered as a MOS device at an upper surface and a PN junction structure at a lower surface, which are connected with each other via a drift region therebetween. Therefore, in FIG. 3, the IGBT is schematically represented by one PN junction and one MOS device.

In a sixth preferred embodiment as shown in FIG. 4, four sub-devices of four composite IGBT devices of the same type constitute a full-bridge circuit. The full-bridge circuit is configured to control a current in a primary coil of a transformer. Other four sub-devices may be used as simple accelerating tubes to accelerate an operating speed of the circuit. Alternatively, the other four sub-devices may also be connected similarly to the full-bridge circuit to control a current direction in a primary coil of another transformer. In this case, a multiplex voltage output can be obtained.

The individual IGBT devices constituting the one-piece structure in the present invention are significantly separated from each other spatially, for example, by a spacing between 250 micrometers (μm) and 1 millimeter (mm)

What described above are only preferred embodiments of the present invention but are not intended to limit the scope of the present invention. People skilled in this field may proceed with a variety of variations and replacements without departing from the scope of the present invention. For example, in the schematic view of the present invention, the sub-IGBTs have NPT (non-punch through) structures. However, it is obvious that, the sub-IGBTs may also have any of the structures of PT (punch through) type, field stop type, grooved IGBT, or super junction device. As another example, the devices of the present invention may be made form silicon materials. Also, the devices may be made from SiC, GaN or any other material. These should be covered within the scope of the present invention. Therefore, the scope of the present invention is only defined by the claims.

1. A composite one-piece insulated gate bipolar transistor (IGBT) device, comprising at least two IGBT devices, wherein drift regions of the at least two IGBT devices connect with each other and electrodes of the at least two IGBT devices are led out separately from each other.

2. The composite one-piece IGBT device of claim 1, wherein the composite IGBT device is in a “ [symbol] ” shape consisting of four IGBT devices, with the drift region of each of the IGBT devices connecting with those of the adjacent IGBT devices.

3. The composite one-piece IGBT device of claim 2, wherein the IGBT device at the upper left corner and the IGBT device at the lower right corner are connected in parallel to form a first block, and the IGBT device at the upper right corner and the IGBT device at the lower left corner are connected in parallel to form a second block.

4. The composite one-piece IGBT device of claim 1, wherein the composite IGBT device consists of two IGBT devices which have the same size or have different sizes.

5. The composite one-piece IGBT device of claim 1, wherein the composite IGBT device consists of two IGBT devices having different sizes, and one of the two IGBT devices that occupies a larger chip area acts as a primary switching device for switching a large current, while the other IGBT device that occupies a smaller chip area acts as an auxiliary device for accelerating the switching action of the primary switching device.

6. The composite one-piece IGBT device of claim 1, wherein the IGBT devices forming the one-piece structure are spaced apart from each other by more than 250 micrometers (μm).

7. The composite one-piece IGBT device of claim 1, wherein the IGBT devices are isolated from each other through one or a combination of extending the spacing there between, forming a field ring or forming a field plate.

8. A producing method of a composite one-piece IGBT device, comprising the following steps of:
8.1 forming a channel region of a second conductivity type on a substrate wafer of a first conductivity type through impurity doping and diffusion; preparing a gate, and forming a source region of the first conductivity type through impurity implantation and doping activation; depositing a protective medium layer, forming a contact via, and performing a metallization wiring process and upper surface passivation;
8.2 before, during or after the step 8.1, forming a groove on the upper surface and depositing a passivation layer to protect the bared portion;
8.3 thinning a back surface of the wafer;
8.4 performing ion implantation doping, annealing and metallization on the back surface;
8.5 before, during or after the step 8.4, forming a back-surface groove on the back surface at a position corresponding to the upper-surface groove; and
8.6 slicing the wafer, and leading out electrodes of individual devices of the composite IGBT device respectively; and packing the composite IGBT device.

9. The producing method of a composite one-piece IGBT device of claim 8, wherein the upper-surface groove is formed in the step 8.2 through wet etching, dry etching, dry-and-wet etching or laser ablating.

10. The producing method of a composite one-piece IGBT device of claim 8, wherein the back-surface groove is formed in the step 8.5 through the following steps of:
8.5.1 performing light exposure on the back surface at a position corresponding to the upper-surface groove through a double-side aligned photolithography process; and
8.5.2 forming the back-surface groove through wet etching, dry etching, dry-and-wet etching or laser ablating.

11. A use of a composite one-piece IGBT device, wherein when one or one set of sub-devices of the composite IGBT is turned on, the other one or the other set of sub-devices of the composite IGBT is just turned off so that the two or the two sets of sub-devices can promote each other's turning-on/off speed.
